(19) United States
(12) Patent Application Publication
(10) Pub. No.: US 2006/0124382 A1
(43) Pub. Date: Jun. 15, 2006

(54) Corner audio enclosure and advertising means

(76) Inventor: Dilip Bhavnani, Beverly Hills, CA (US)

Correspondence Address: THE SONI LAW FIRM, 55 S. LAKE AVE SUITE 720, PASADENA, CA, 91101, US

(21) Appl. No.: 11/012,542

(22) Filed: Dec. 14, 2004

(51) Int. Cl. A47B 81/06; H05K 5/00

(52) U.S. Cl. 181/199; 181/153

(57) ABSTRACT

An audio enclosure for a receiver unit of radio or other audio signal source use which is specifically designed to fit into a corner and provide sound quality which is improved by such corner placement. The envelope and angularly displaced speaker output location geometry featured in the invention provide an enhanced stereophonic sound quality which fills the room or other space with perimeter emanating sound having richer and fuller sound quality, particularly in the lower frequency ranges. In addition, the generally round cylindrical envelope enclosure shape of the invention is such that it fits more tightly into a corner or recess than conventional square, trapezoidal or rectangular shaped radio enclosures. The outer surfaces of the enclosure, having relatively smooth surfaces, are well-suited for application of art work, logos and graphics for advertising and promotional purposes.

### BACKGROUND OF THE INVENTION

The present invention relates to the enclosure for a receiver unit of a radio or other audio signal source use which is specifically designed to fit into a corner and provide sound quality which is improved by such corner placement. The envelope and angularly displaced speaker output location geometry featured in the invention provide an enhanced stereophonic sound quality which fills the room or other space with perimeter emanating sound having richer and fuller sound quality, particularly in the lower frequency ranges. In addition, the generally round cylindrical envelope enclosure shape of the invention is such that it fits more tightly into a corner or recess than conventional square, trapezoidal or rectangular shaped radio enclosures.

Radios are well known devices. More specifically, small and portable radio devices are commonly found in most homes or businesses. Conventional radio enclosure devices, however, are typically configured in a rectangular or other geometric shape having at least two parallel sides with the speaker(s) typically mounted on the frontal surface of the radio. This common design has two inherent disadvantages in that the envelope shape can become cumbersome and when placed in an out of the way corner, the generally rectangular shape does not efficiently fit into the corner recess but instead, leaves a great deal of space between the back of the radio and the inside corner. Such a poor fit results in user dissatisfaction as the radio then projects outwardly from the corner walls to an undesireable extent. Additionally, the frontal mounting of the speaker outlet ports, when used with the small and relatively inexpensive speakers typically found in conventional radios results in poor sound quality and a lack of bass, commonly referred to as tinney sound. Overcompensation for this tinney sound by adjustment of the tone control to emphasize the lower frequency response only increases the distortion of the speaker output sound.

For the foregoing reasons, there is a need for a compact enclosure which will fit more tightly into an inside corner recess and the placement of which into a corner provides improved perceived sound quality to the user.

### SUMMARY OF THE INVENTION

The present invention provides for an audio enclosure constructed to fit within a corner recess. The invention includes at least two speakers which are mounted inside the enclosure. These speakers are mounted tangentially and perpendicular to the inner surface of speaker outlet ports radially disposed inside the enclosure shell in the front half quadrant of the enclosure. These speaker outlet ports are positioned at an obtuse angle with respect to the vertical centerline of the front circumferential surface of the audio enclosure, as typically perceived by the user.

The present invention satisfies the needs for a small personal size radio which will fit into an inside corner with less residual open space between the rear face of the radio and the inside corner vertex than a conventional radio with a singularly coplaner elongated rear surface. When placed into an inside corner, the present invention will present the user with a lesser projection from the vertex to the radio front surface then conventional desk or portable radios.

The present invention also satisfies the need for a small personal size radio having a sound quality which is enhanced and otherwise perceptibly improved when placed into an inside corner of a room.

### BRIEF DESCRIPTION OF THE DRAWINGS

FIG. 1 is a top front perspective view of a preferred embodiment of the Comer Audio Enclosure.

FIG. 2 is a front view of a preferred embodiment of the Comer Audio Enclosure.

FIG. 3 is a left side view of a preferred embodiment of the Comer Audio Enclosure.

FIG. 4 is a right side view of a preferred embodiment of the Comer Audio Enclosure.

FIG. 5 is a top plan view of a preferred embodiment of the Comer Audio Enclosure.

FIG. 6 is a bottom plan view of a preferred embodiment of the Comer Audio Enclosure.

FIG. 7 is a rear view of a preferred embodiment of the Comer Audio Enclosure.

FIG. 8 is a top front perspective view of a preferred embodiment of the Comer Audio Enclosure with the antenna lowered.

FIG. 9 is a top front perspective view of a preferred embodiment of the Comer Audio Enclosure as it would typically be located in a corner.

### DETAILED DESCRIPTION OF THE PREFERRED EMBODIMENT

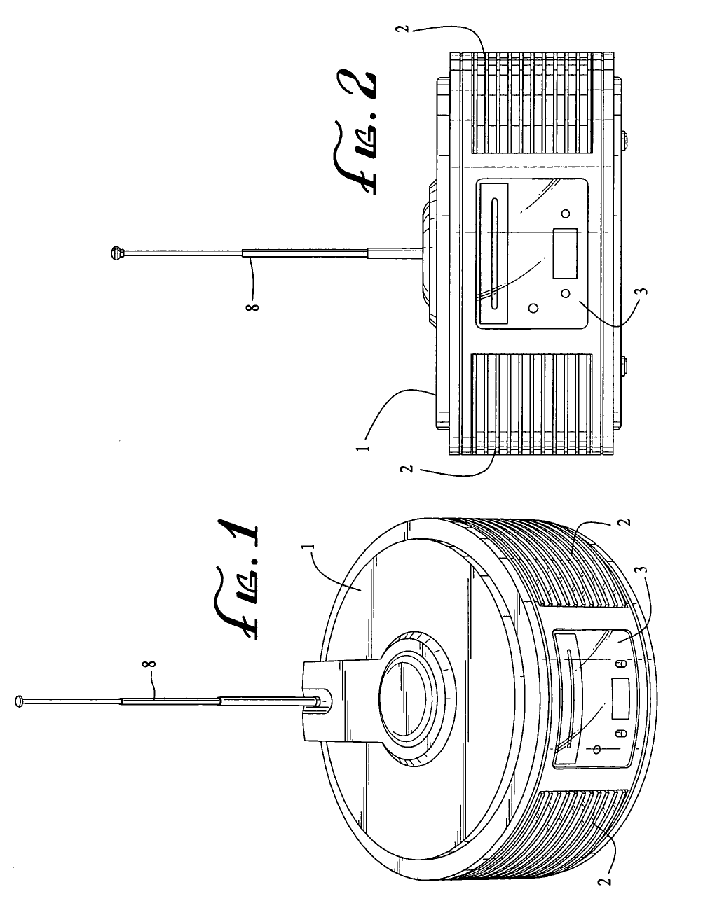

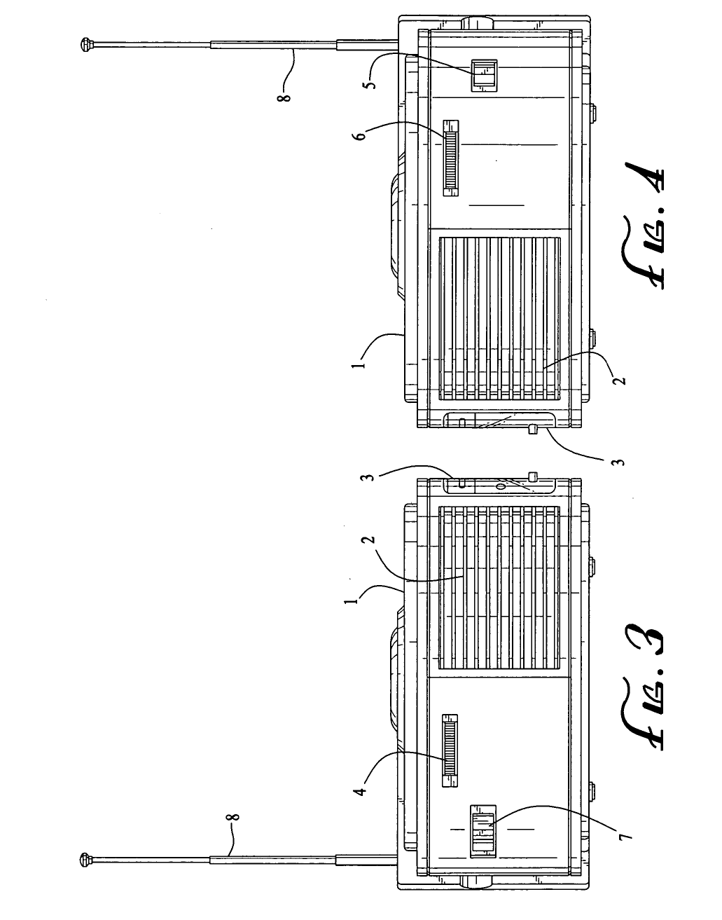

Referring to FIG. 1, a top front perspective view of a preferred embodiment of the Comer Audio Enclosure is illustrated. The electronic components of and function of a commonly used radio or audio device are well known to those skilled on the art. The depicted preferred embodiment of the Comer Audio Enclosure comprises an outer shell enclosure (1) which is generally round and vertically cylindrical in shape (See FIG. 5). The enclosure includes at least two speaker output ports (2) integrally located on the curved surface of the enclosure (1). The speaker outlet ports (2) comprise a perforated grill structure, commonly known in the art, such that sound may pass from the speaker through the perforations to the listener. An internal speaker, of the type well known to those skilled in the art, is affixed to the inside surface of the enclosure shell (1) disposed radially inward from and perpendicular to each of the output ports (2). Referring to FIG. 2, the front outer surface of the enclosure includes a face plate (3) comprising a frequency selection or audio input type device and may further include other control features, such as a clock or mode settings, the details of which are well known to those skilled in the art.

As illustrated in FIGS. 2, 3 and 4, the speaker outlet ports (2) are located in a position which permits the sound emanating therefrom to project radially outward from the enclosure at an obtuse angle with respect to the vertical centerline of the face plate (3), rather than projecting perpendicularly outward from a position coplaner to the tangential front surface of the face plate (3).

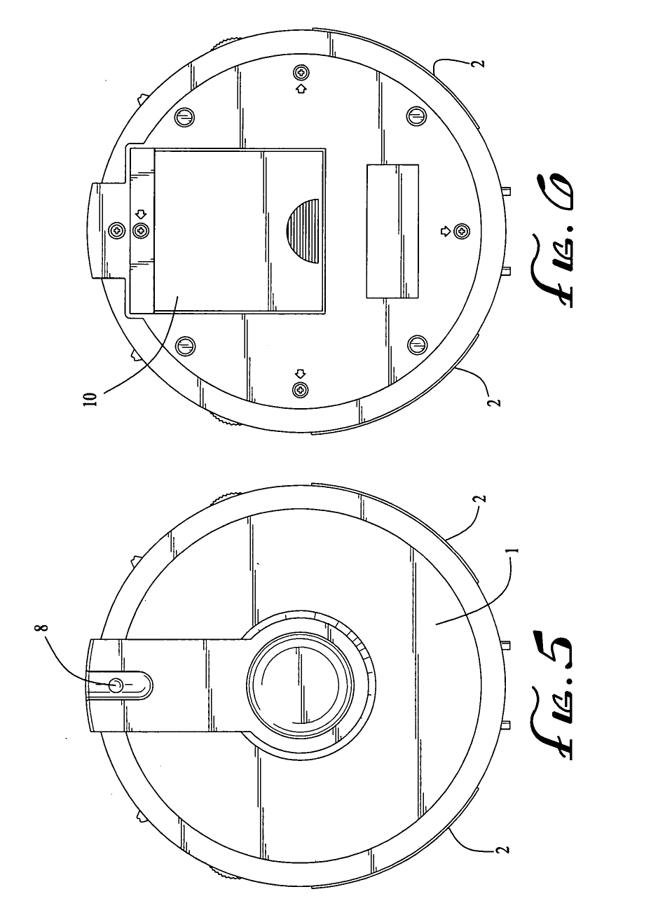

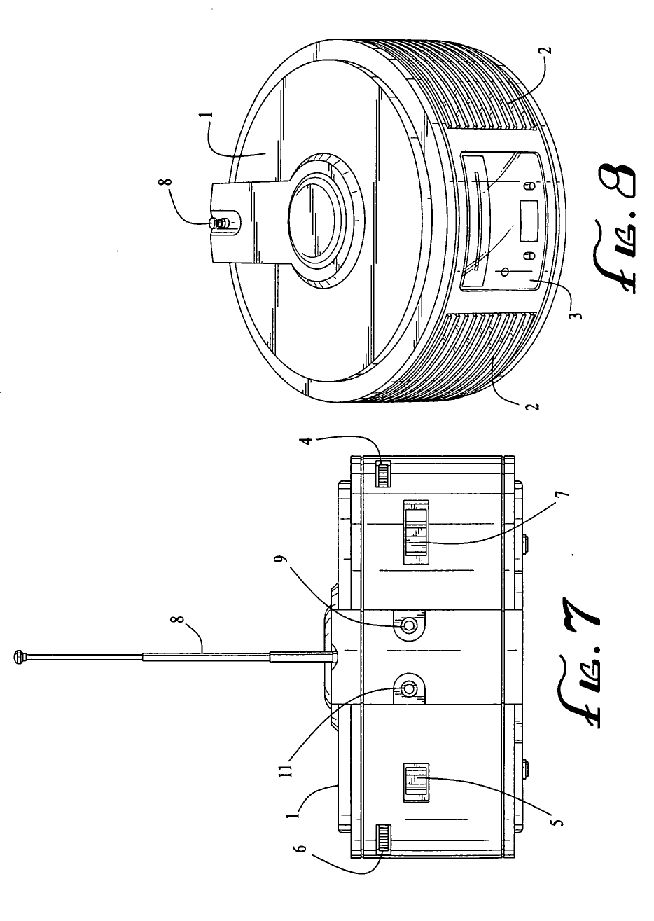

The preferred embodiment may also include switches or dial controls for typical functions associated with a radio, well known to those skilled in the art, and as depicted in FIGS. 3 and 4, which may include a volume control (4), alarm set/control (5), tuning dial (6), radio band width selection switch (7) and an antenna (8).

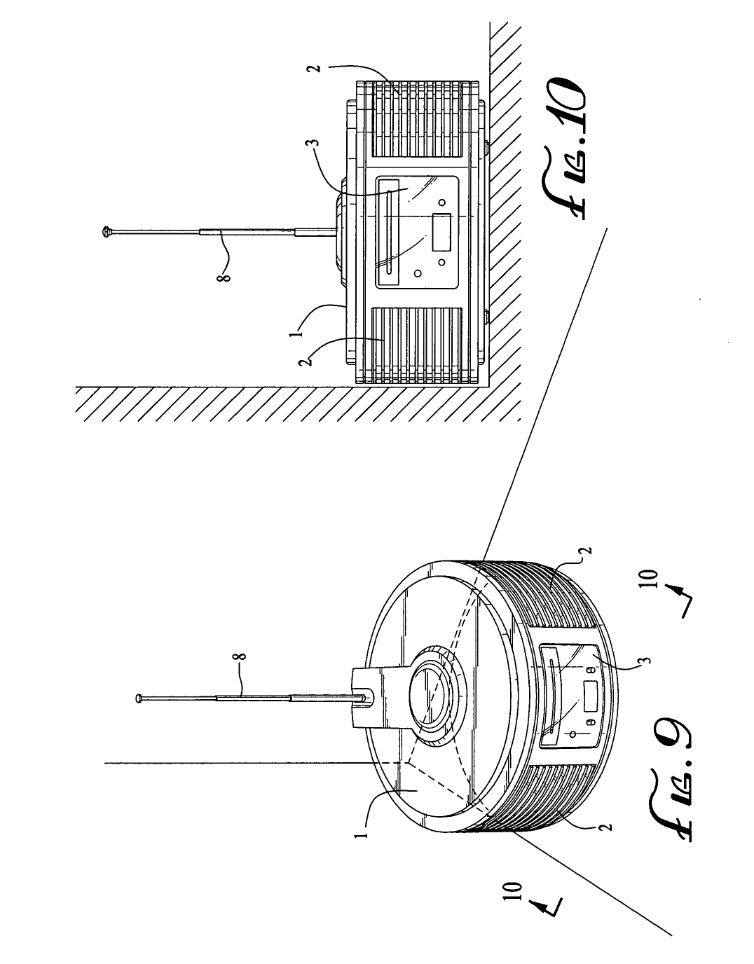

As is well known to those skilled in the art, the preferred embodiment of the Comer Audio Enclosure may operate from an external power source or alternatively may rely upon a battery source for the power supply. As illustrated in FIGS. 7 and 8, the preferred Corner Audio Enclosure embodiment may further comprise a female input jack (9) to facilitate the insertion of a plug from an external power supply, and a battery compartment (10) within which ordinary and commonly known batteries may be stored and electrically connected to the radio electronics to serve as a power supply for the invention. The preferred embodiment may further comprise a headphone jack (11), well known to those skilled in the art, to permit sound to emanate from the invention via the speaker outlet ports (2) or alternatively, through a headphone set connected to the invention by insertion into the headphone jack (11).

As shown in FIGS. 9 and 10, the preferred embodiment of the Corner Audio Enclosure is contemplated for use in a corner location, usually in a room or office. FIGS. 9 and 10 show the relative location of the speaker outlets when placed in a corner and illustrate the perimeter enhanced sound which is obtained by such placement, as the speaker axis, emanating from the ports in approximately the location shown by the speaker outlet ports (2) in FIG. 9 would be parallel to the wall surface against which the invention is placed.

While the preferred embodiment is shown as a round object, there is no reason the structure must be entirely round. It could be oval shaped and still achieve the desired purpose of enhanced sound quality and corner fitting. Similarly, the enclosure may have some flat surfaces, for example, as a hexagonal shape, and still achieve these two purposes. The enclosure may have one or more horizontal flat surfaces about its circumference and still be within the shapes contemplated by this invention, for example, if the designer wishes to have the face plate or a portion of the rear surface become a flat horizontal surface, tangentially oriented with respect to the diameter of the enclosure.

The outer surfaces of the enclosure, having relatively smooth surfaces, are well-suited for application of art work, logos and graphics for advertising and promotional purposes.

What is claimed is:

1. A generally cylindrical shaped audio enclosure for placement in a corner comprising:
an outer shell including at least two speaker placement locations along the circumference of the outer shell;
speaker means attached at each speaker placement location such that sounds emitted from the speaker means, when operational, are projected radially outward in directions whereby the sound projection axis is generally parallel to at least one of the planes which form the corner behind the enclosure; and
electronics and sound generating means located within the enclosure.

2. The audio enclosure of claim 1, wherein the speaker locations in the enclosure result in a sound projection axis of each speaker which is at an angle measuring between 15 and 120 degrees with respect to sound projection axis of the other speaker.

3. The audio enclosure of claim 1, wherein the speaker locations in the enclosure are equidistant or equi-angled from a centerline bissecting the frontal surface of the enclosure.

4. The audio enclosure of claim 1, wherein graphical or advertising material is imprinted on at least one surface for the purpose of providing advertising or promotion.

5. An audio enclosure comprising a generally cylindrically shaped outer shell;
said shell having at least one truncated tangentially coplaner vertical surface on the outer shell and at least two integral perforated speaker locations arranged at obtuse angles with respect to the vertical centerline of the frontal tangential surface of the outer shell;
said speaker locations each connected to a speaker means whereby a sound emitted from the speaker means, when operational, is projected radially outward in a direction such that the sound projection axis is generally parallel to at least one of the planes which form the corner where the enclosure is placed.

6. The enclosure of claim 5, wherein the speaker locations are located in the enclosure so that the sound projection axis of each speaker is positioned at an angle measuring between 15 and 120 degrees with respect to sound projection axis of the other speaker.

7. The enclosure of claim 6, wherein said angle is bisected by the vertical centerline of the frontal tangential surface of the outer shell.

8. The audio enclosure of claim 4, wherein graphical or advertising material is imprinted on at least one surface for the purpose of providing advertising or promotion.

9. A method for perimeter audio sound generation within a room by means of using:
an enclosure comprising a generally cylindrically shaped outer shell and having
a outer shell including at least two speaker placement locations along the circumference of the outer shell;
speaker means attached at each speaker placement location such that sounds emitted from the speaker means, when operational, are projected radially outward in directions whereby the sound projection axis is generally parallel to at least one of the planes which form the corner behind the enclosure; and
electronics and sound generating means located within the enclosure.

10. The method of claim 9, wherein the number of speaker placement locations is two.

11. The method claim 9, wherein the speaker placement locations are located in an enclosure whereby the sound projection axis of each speaker is positioned at an angle measuring between 15 and 120 degrees with respect to sound projection axis of the other speaker.

12. The method of claim 11, wherein said angle is bisected by the vertical centerline of the frontal tangential surface of the outer shell.

13. The method of claim 11, whereby the projection axis of at least one speaker is parallel to a perpendicular tangential plane against which the audio enclosure is located.

14. A method of advertising or promotion comprising the imprinting of printed or graphical material on a surface of a generally cylindrical shaped audio enclosure for placement in a corner having:
an outer shell including at least two speaker placement locations along the circumference of the outer shell;
speaker means attached at each speaker placement location such that sounds emitted from the speaker means, when operational, are projected radially outward in directions whereby the sound projection axis is generally parallel to at least one of the planes which form the corner behind the enclosure; and
electronics and sound generating means located within the enclosure.

15. A method of advertising or promotion comprising the imprinting of printed or graphical material on a surface of an audio enclosure for placement in a corner having a generally cylindrically shaped outer shell;
said shell having at least one truncated tangentially coplaner vertical surface on the outer shell and at least two integral perforated speaker locations arranged at obtuse angles with respect to the vertical centerline of the frontal tangential surface of the outer shell;
said speaker locations each connected to a speaker means whereby a sound emitted from the speaker means, when operational, is projected radially outward in a direction such that the sound projection axis is generally parallel to at least one of the planes which form the corner where the enclosure is placed.
